(19) United States
(12) Patent Application Publication
(10) Pub. No.: US 2025/0300631 A1
(43) Pub. Date: Sep. 25, 2025

(54) ACOUSTIC WAVE FILTER AND HIGH FREQUENCY CIRCUIT

(71) Applicant: Murata Manufacturing Co., Ltd., Kyoto (JP)

(72) Inventor: Minoru IWANAGA, Kyoto (JP)

(21) Appl. No.: 18/976,434

(22) Filed: Dec. 11, 2024

(30) Foreign Application Priority Data
Mar. 21, 2024 (JP) 2024-044952

(51) Int. Cl. H03H 9/64; H03H 9/25

(52) U.S. Cl. CPC H03H 9/6423; H03H 9/25

(57) ABSTRACT

A filter has a pass band including a reception band which is a first band and a reception band which is a second band and has input terminals, an output terminal, a switch circuit including a common terminal and selection terminals, a series-arm resonator connected between the selection terminal and the input terminal, a series-arm resonator connected between the selection terminal and the input terminal, and an acoustic wave resonator connected between the common terminal and the output terminal.

### CROSS REFERENCE TO RELATED APPLICATION

This application claims priority from Japanese Patent Application No. 2024-044952 filed on Mar. 21, 2024. The content of this application is incorporated herein by reference in its entirety.

### BACKGROUND ART

The present disclosure relates to an acoustic wave filter and a high frequency circuit.

In order to improve the data rate in a radio link, more and more mobile communication devices, such as mobile phones, support carrier aggregation (CA), dual connectivity (DC), or the like for simultaneous use of a plurality of channels in a plurality of frequency bands or the same frequency band. International Publication No. 2023/276871 discloses a high frequency circuit having a plurality of filters for a plurality of frequency bands.

### BRIEF SUMMARY

However, with the conventional technique described above, it is difficult to decrease the number of filters and suppress degradation of performance in simultaneous communication.

Thus, the present disclosure provides an acoustic wave filter and a high frequency circuit capable of decreasing the number of filters and suppressing degradation of performance in simultaneous communication.

An acoustic wave filter according to an aspect of the present disclosure is an acoustic wave filter having a pass band including a reception band which is a first band and a reception band which is a second band, the acoustic wave filter having: a first input terminal and a second input terminal; an output terminal; a first switch circuit including a first common terminal, a first selection terminal, and a second selection terminal; a first series-arm acoustic wave resonator connected between the first selection terminal and the first input terminal; a second series-arm acoustic wave resonator connected between the second selection terminal and the second input terminal; and an acoustic wave resonator connected between the first common terminal and the output terminal.

A high frequency circuit according to an aspect of the present disclosure has: the acoustic wave filter described above; a first filter having a pass band including a reception band which is a third band; a second filter having a pass band including a reception band which is a fourth band; and a second switch circuit including a second common terminal connected to an antenna connection terminal, a third selection terminal, and a fourth selection terminal. The third selection terminal is connected to the first input terminal of the acoustic wave filter and also connected to the first filter, and the fourth selection terminal is connected to the second input terminal of the acoustic wave filter and also connected to the second filter. A combination of the first band and the third band is a band combination capable of simultaneous communication, and a combination of the second band and the fourth band is a band combination capable of simultaneous communication.

An acoustic wave filter according to an aspect of the present disclosure is an acoustic wave filter switchable between a first pass band including a reception band which is a first band and a second pass band including a reception band which is a second band, the acoustic wave filter having: a first input terminal, a second input terminal, and a third input terminal; a first output terminal and a second output terminal; a first switch circuit including a first common terminal, a second common terminal, a first selection terminal, a second selection terminal, and a third selection terminal; a first series-arm acoustic wave resonator connected between the first selection terminal and the first input terminal; a second series-arm acoustic wave resonator connected between the second selection terminal and the second input terminal; a third series-arm acoustic wave resonator connected between the third selection terminal and the third input terminal; a first acoustic wave resonator connected between the first common terminal and the first output terminal; and a second acoustic wave resonator connected between the second common terminal and the second output terminal.

A high frequency circuit according to an aspect of the present disclosure has: the acoustic wave filter described above; a first filter having a pass band including a reception band which is a third band; a second filter having a pass band including a reception band which is a fourth band; a third filter having a pass band including a reception band which is a fifth band; and a second switch circuit including a third common terminal connected to an antenna connection terminal, a fourth selection terminal, a fifth selection terminal, and a sixth selection terminal. The fourth selection terminal is connected to the first input terminal of the acoustic wave filter and also connected to the first filter, the fifth selection terminal is connected to the second input terminal of the acoustic wave filter and also connected to the second filter, and the sixth selection terminal is connected to the third input terminal of the acoustic wave filter and also connected to the third filter. At least one of a combination of the first band and the third band and a combination of the second band and the third band is a band combination capable of simultaneous communication, at least one of a combination of the first band and the fourth band and a combination of the second band and the fourth band is a band combination capable of simultaneous communication, and at least one of a combination of the first band and the fifth band and a combination of the second band and the fifth band is a band combination capable of simultaneous communication.

The present disclosure is capable of decreasing the number of filters and suppressing degradation of performance in simultaneous communication.

### BRIEF DESCRIPTION OF THE DRAWINGS

FIG. 1 is a circuit configuration diagram of a communication device according to Embodiment 1;

FIG. 2 is a circuit configuration diagram of an acoustic wave filter according to Embodiment 1;

FIG. 3 is a circuit configuration diagram of a communication device according to Embodiment 2;

FIG. 4 is a circuit configuration diagram of a communication device according to Embodiment 3; and

FIG. 5 is a circuit configuration diagram of a communication device according to a modification of Embodiment 3.

### DETAILED DESCRIPTION

Embodiments of the present disclosure are described below in detail using the drawings. Note that the embodiments described below all present a comprehensive or specific example. Numerical values, shapes, materials, constituents, how the constituents are arranged and connected, and the like given in the following embodiments are merely examples and are not intended to limit the present disclosure.

Note that the drawings are each a schematic diagram where exaggeration, omission, or proportional adjustment is made as needed to demonstrate the present disclosure and do not necessarily provide precise depiction. They may differ from actual shapes, position relations, and proportions. Throughout the drawings, configurations that are substantially the same are denoted by the same reference numeral, and repetitive descriptions may be omitted or simplified.

In the descriptions below, being “connected” includes not only being directly connected by a connection terminal and/or a wiring conductor, but also being electrically connected with a different circuit element interposed in between. “A being switchably connected to B” means that connection and disconnection between A and B can be switched and that A is connected to B with a switch being interposed in between. Note that “A being connected to B” includes “A being switchably connected to B.” “C being connected between A and B” means that one end of C is connected to A and the other end of C is connected to B and means that C is connected in series to a path connecting A and B. The “path connecting A and B” means a path formed by a conductor electrically connecting A and B.

A “terminal” is a point where a conductor between elements terminates. Note that when a conductor between elements has sufficiently low impedance, the terminal is interpreted not only as a single point, but also as any given point on the conductor between the elements or the entire conductor.

A “pass band of a filter” is part of the frequency spectrum delivered by the filter and is defined as a frequency band where output power does not attenuate from the maximum output power by 3 dB or greater. Thus, the higher band end and the lower band end of the pass band of a band pass filter are respectively identified as the higher frequency one and the lower frequency one of two points of output power attenuated from the maximum output power by 3 dB.

A “transmission band” means a frequency band used for transmission by a communication device, and a “reception band” means a frequency band used for reception by a communication device. For example, in a frequency division duplex (FDD) band, frequency bands different from each other (e.g., an uplink band and a downlink band) are used as a transmission band and a reception band. Also, for example, in a time division duplex (TDD) band, the same frequency band is used as a transmission band and a reception band.

A “band combination capable of simultaneous communication” means a plurality of bands defined in advance as a combination capable of simultaneous transmission, simultaneous reception, or simultaneous transmission and reception. The “band combination capable of simultaneous communication” is defined by, e.g., a standards organization (such as, e.g., 3rd Generation Partnership Project (3GPP) (registered trademark) and Institute of Electrical and Electronics Engineers (IEEE)). The “band combination capable of simultaneous communication” is defined as a band combination for, for example, CA, E-UTRAN New Radio-Dual Connectivity (EN-DC), New Radio-Dual Connectivity (NR-DC), or New Radio E-UTRAN-Dual Connectivity (NE-DC).

Terms expressing the relation between elements, such as “parallel” and “perpendicular,” terms expressing the shapes of elements, such as “rectangular,” and ranges of numerical values not only express strict meanings, but also mean that ranges that are substantially equivalent are also included, e.g., error within about several percents.

### Embodiment 1

Embodiment 1 is described. A communication device 5 according to the present embodiment can be used to provide wireless communications. For example, the communication device 5 can be implemented in user equipment (UE) in a cellular network (also referred to as a mobile network), such as a mobile phone, a smartphone, a tablet computer, or a wearable device. In another example, implementation of the communication device 5 can provide wireless communications to an Internet of Things (IoT) sensor device, a medical/healthcare device, an automobile, an unmanned aerial vehicle (UAV) (what is called a drone), or an automated guided vehicle (AGV). In yet another example, implementing the communication device 5 can provide wireless communications at a wireless access point or a wireless hot spot.

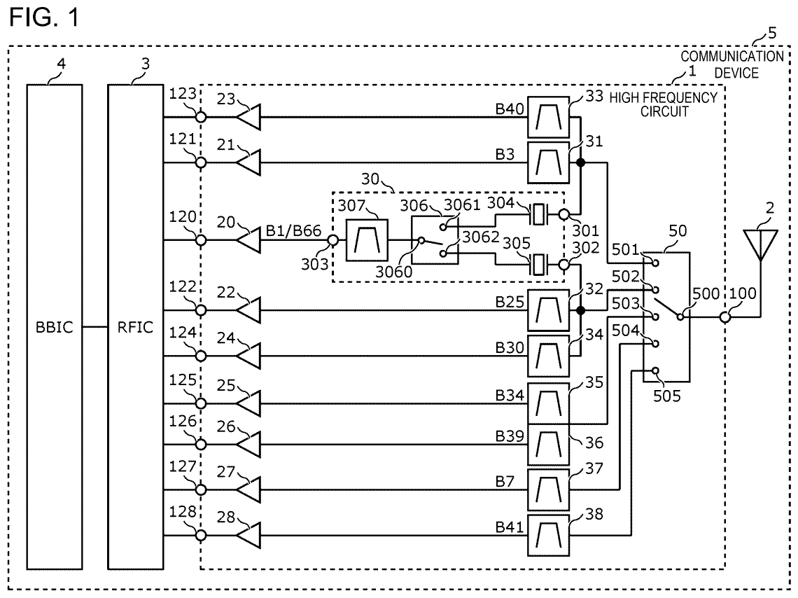

The circuit configurations of the communication device 5 and a high frequency circuit 1 according to the present embodiment are described with reference to FIG. 1. FIG. 1 is a circuit configuration diagram of the communication device 5 according to the present embodiment.

Note that FIG. 1 is an exemplary circuit configuration, and the communication device 5 may be implemented using any of various kinds of circuit implementation and circuit technology. Thus, the descriptions of the communication device 5 provided below are not to be interpreted as limitative.

Also, in FIG. 1, numbers with the letter B that are written next to filters denote numbers identifying frequency bands in LTE and/or 5G NR. For instance, “B1” denotes Band 1 for LTE and/or n1 for 5G NR. Note that the frequency bands shown in FIG. 1 are presented as examples to facilitate understanding by those skilled in the art, and the frequency bands corresponding to the respective filters are not limited to what is shown in FIG. 1.

### 1.1. Circuit Configuration of the Communication Device 5

First, the circuit configuration of the communication device 5 according to the present embodiment is described with reference to FIG. 1. The communication device 5 has the high frequency circuit 1, an antenna 2, a radio frequency integrated circuit (RFIC) 3, and a baseband integrated circuit (BBIC) 4.

The high frequency circuit 1 can deliver high frequency signals between the antenna 2 and the RFIC 3. The circuit configuration of the high frequency circuit 1 will be described later.

The antenna 2 is connected to an antenna connection terminal 100 of the high frequency circuit 1. The antenna 2 can receive a high frequency signal from the high frequency circuit 1 and transmit it to the outside of the communication device 5. The antenna 2 can also receive a high frequency signal from the outside of the communication device 5 and output it to the high frequency circuit 1. Note that the antenna 2 does not need to be included in the communication device 5. Also, the communication device 5 may further include one or more additional antennas in addition to the antenna 2. In this case, a switch circuit 50 may include one or more additional common terminals, and the one or more additional antennas may be connected to the one or more additional common terminals.

The RFIC 3 is an example of a signal processing circuit that processes a high frequency signal. Specifically, the RFIC 3 can perform signal processing on a transmission signal inputted from the BBIC 4 using up-conversion or the like and output a high frequency transmission signal thus generated by the signal processing to the high frequency circuit 1. The RFIC 3 can further perform signal processing on a high frequency reception signal inputted thereto through a reception path in the high frequency circuit 1 using down-conversion or the like and output a reception signal thus generated by the signal processing to the BBIC 4. Also, the RFIC 3 may have a controller that controls a switch, a power amplifier, and the like in the high frequency circuit 1. Note that some or all of the functions of the RFIC 3 as a controller may be included in the outside of the RFIC 3 and may be included in, for example, the BBIC 4 or the high frequency circuit 1.

The BBIC 4 is a baseband signal processing circuit that performs signal processing using a frequency band of lower frequencies than a high frequency signal delivered by the high frequency circuit 1. Examples of a signal processed by the BBIC 4 include an image signal for displaying an image and/or an audio signal for a phone call on a speaker. Note that the BBIC 4 does not have to be included in the communication device 5.

### 1.2. Circuit Configuration of the High Frequency Circuit 1

Next, the circuit configuration of the high frequency circuit 1 according to the present embodiment is described with reference to FIG. 1. The high frequency circuit 1 has low-noise amplifiers 20, 21, 22, 23, 24, 25, 26, 27 and 28, filters 30, 31, 32, 33, 34, 35, 36, 37, and 38, the switch circuit 50, the antenna connection terminal 100, and high frequency output terminals 120, 121, 122, 123, 124, 125, 126, 127, and 128.

The antenna connection terminal 100 is an external connection terminal of the high frequency circuit 1 and is connected to the antenna 2 outside the high frequency circuit 1. Also, the antenna connection terminal 100 is connected to the switch circuit 50 inside the high frequency circuit 1. The high frequency circuit 1 can thus receive a reception signal from the antenna 2 via the antenna connection terminal 100.

The high frequency output terminals 120 to 128 are external connection terminals of the high frequency circuit 1 and are connected to the RFIC 3 outside the high frequency circuit 1. The high frequency output terminals 120 to 128 are also connected to the output ends of the low-noise amplifiers 20 to 28, respectively, inside the high frequency circuit 1. Thus, the high frequency circuit 1 can supply signals received in the first to tenth bands and amplified by the low-noise amplifiers 20 to 28 to the RFIC 3 via the high frequency output terminals 120 to 128, respectively.

The input ends of the low-noise amplifiers 20 to 28 are connected to the filters 30 to 38, respectively. The output ends of the low-noise amplifiers 20 to 28 are connected to the high frequency output terminals 120 to 128, respectively. Thus, the low-noise amplifier 20 can amplify signals received in the first and second bands. The low-noise amplifiers 21 to 28 can amplify signals received in the third to tenth bands, respectively.

The low-noise amplifiers 20 to 28 are formed of field-effect transistors (FETs) and can be manufactured using a semiconductor material. For example, single-crystal silicon, gallium nitride (GaN), or silicon carbide (SiC) can be used as the semiconductor material. Note that amplification transistors for the low-noise amplifiers 20 to 28 are not limited to FETs. For example, some or all of the low-noise amplifiers 20 to 28 may be formed of a bipolar transistor.

Note that some or all of the low-noise amplifiers 20 to 28 may be not included in the high frequency circuit 1. In this case, some or all of the low-noise amplifiers 20 to 28 may be connected between the RFIC 3 and the high frequency output terminals 120 to 128 or may be included in the RFIC 3.

The filter 30 is an acoustic wave filter and is a band pass filter having a pass band including a reception band which is a first band (B1) and a reception band which is a second band (B66). One end of the filter 30 is connected to the input end of the low-noise amplifier 20, and the other ends of the filter 30 are connected to selection terminals 501 and 502 of the switch circuit 50.

In the present embodiment, as the first band, Band 1 for LTE or n1 for 5G NR can be used, but the first band is not limited to these. Also, as the second band, Band 66 for LTE or n66 for 5G NR can be used, but the second band is not limited to these.

The filter 30 includes input terminals 301 and 302, an output terminal 303, series-arm resonators 304 and 305, a switch circuit 306, and an acoustic wave resonator 307.

The input terminal 301 is an example of the first input terminal and is connected to the selection terminal 501 of the switch circuit 50 outside the filter 30 and connected to the series-arm resonator 304 inside the filter 30.

The input terminal 302 is an example of the second input terminal and is connected to the selection terminal 502 of the switch circuit 50 outside the filter 30 and connected to the series-arm resonator 305 inside the filter 30.

The output terminal 303 is connected to the input end of the low-noise amplifier 20 outside the filter 30 and is connected to the acoustic wave resonator 307 inside the filter 30.

The series-arm resonator 304 is an example of the first series-arm acoustic wave resonator and is connected between the input terminal 301 and the switch circuit 306.

The series-arm resonator 305 is an example of the second series-arm acoustic wave resonator and is connected between the input terminal 302 and the switch circuit 306.

The switch circuit 306 is an example of the first switch circuit and is connected between the acoustic wave resonator 307 and the series-arm resonators 304 and 305. The switch circuit 306 includes a common terminal 3060 and selection terminals 3061 and 3062. The common terminal 3060 is an example of the first common terminal and is connected to the acoustic wave resonator 307. The selection terminal 3061 is an example of the first selection terminal and is connected to the series-arm resonator 304. The selection terminal 3062 is an example of the second selection terminal and is connected to the series-arm resonator 305.

In such a connection configuration, the switch circuit 306 can connect the common terminal 3060 exclusively to the selection terminals 3061 or 3062 based on, e.g., a control signal from the RFIC 3. The switch circuit 306 is formed of, for example, a single-pole, double-throw (SPDT) switch circuit.

The acoustic wave resonator 307 is connected between the output terminal 303 and the common terminal 3060 of the switch circuit 306. The acoustic wave resonator 307 is selectively connected to the series-arm resonators 304 and 305 via the switch circuit 306. The resonant frequencies of the series-arm resonators 304 and 305 may be included in the pass band of the filter 30, and the pass band of the filter 30 may be formed by them.

The filter 31 is an example of the first filter and is a band pass filter having a pass band including a reception band which is a third band (B3). One end of the filter 31 is connected to the input end of the low-noise amplifier 21, and the other end of the filter 31 is connected to the selection terminal 501 of the switch circuit 50.

A combination of the first band and the third band is a band combination capable of simultaneous communication. As such a third band, Band 3 for LTE or n3 for 5G NR can be used, but the third band is not limited to these.

The filter 32 is an example of the second filter and is a band pass filter having a pass band including a reception band which is a fourth band (B25). One end of the filter 32 is connected to the input end of the low-noise amplifier 22, and the other end of the filter 32 is connected to the selection terminal 502 of the switch circuit 50.

A combination of the second band and the fourth band is a band combination capable of simultaneous communication. As such a fourth band, Band 25 for LTE or n25 for 5G NR can be used, but the fourth band is not limited to these.

The filter 33 is an example of the third filter and is a band pass filter having a pass band including a reception band which is a fifth band (B40). One end of the filter 33 is connected to the input end of the low-noise amplifier 23, and the other end of the filter 33 is connected to the selection terminal 501 of the switch circuit 50. Note that the filter 33 does not have to be included in the high frequency circuit 1.

A combination of the first band and the fifth band is a band combination capable of simultaneous communication. As such a fifth band, Band 40 for LTE or n40 for 5G NR can be used, but the fifth band is not limited to these.

The filter 34 is an example of the fourth filter and is a band pass filter having a pass band including a reception band which is a sixth band (B30). One end of the filter 34 is connected to the input end of the low-noise amplifier 24, and the other end of the filter 34 is connected to the selection terminal 502 of the switch circuit 50. Note that the filter 34 does not have to be included in the high frequency circuit 1.

A combination of the second band and the sixth band is a band combination capable of simultaneous communication. As such a sixth band, Band 30 for LTE or n30 for 5G NR can be used, but the sixth band is not limited to these.

The filter 35 is an example of the fifth filter and is a band pass filter having a pass band including a reception band which is a seventh band (B34). One end of the filter 35 is connected to the input end of the low-noise amplifier 25, and the other end of the filter 35 is connected to a selection terminal 503 of the switch circuit 50. Note that the filter 35 does not have to be included in the high frequency circuit 1.

The filter 36 is an example of the sixth filter and is a band pass filter having a pass band including a reception band which is an eighth band (B39). One end of the filter 36 is connected to the input end of the low-noise amplifier 26, and the other end of the filter 36 is connected to the selection terminal 503 of the switch circuit 50. Note that the filter 36 does not have to be included in the high frequency circuit 1.

A combination of the seventh band and the eighth band is a band combination capable of simultaneous communication. As such a seventh band, Band 34 for LTE or n34 for 5G NR can be used, and as the eighth band, Band 39 for LTE or n39 for 5G NR can be used, but the seventh band and the eighth band are not limited to these.

The filter 37 is an example of the seventh filter and is a band pass filter having a pass band including a reception band which is a ninth band (B7). One end of the filter 37 is connected to the input end of the low-noise amplifier 27, and the other end of the filter 37 is connected to a selection terminal 504 of the switch circuit 50. Note that the filter 37 does not have to be included in the high frequency circuit 1.

A combination of the first band and the ninth band and a combination of the second band the ninth band are both a band combination capable of simultaneous communication. As such a ninth band, Band 7 for LTE or n7 for 5G NR can be used, but the ninth band is not limited to these.

The filter 38 is an example of the eighth filter and is a band pass filter having a pass band including a reception band which is a tenth band (B41). One end of the filter 38 is connected to the input end of the low-noise amplifier 28, and the other end of the filter 38 is connected to a selection terminal 505 of the switch circuit 50. Note that the filter 38 does not have to be included in the high frequency circuit 1.

A combination of the first band and the tenth band and a combination of the second band the tenth band are both a band combination capable of simultaneous communication. As such a tenth band, Band 41 for LTE or n41 for 5G NR can be used, but the tenth band is not limited to these.

The switch circuit 50 is an example of the second switch circuit and is connected between the antenna connection terminal 100 and the filters 30 to 38. Specifically, the switch circuit 50 includes a common terminal 500 and the selection terminals 501 to 505. The common terminal 500 is an example of the second common terminal and is connected to the antenna connection terminal 100. The selection terminal 501 is an example of the third selection terminal and is connected to the filters 30, 31, and 33. The selection terminal 502 is an example of the fourth selection terminal and is connected to the filters 30, 32, and 34. The selection terminal 503 is an example of the fifth selection terminal and is connected to the filters 35 and 36. The selection terminal 504 is an example of the sixth selection terminal and is connected to the filter 37. The selection terminal 505 is an example of the seventh selection terminal and is connected to the filter 38. Note that the selection terminals 503 to 505 do not have to be included in the switch circuit 50.

In such a connection configuration, the switch circuit 50 can connect the common terminal 500 to the selection terminals 501 to 505 based on, e.g., a control signal from the RFIC 3. For example, the switch circuit 50 can connect the common terminal 500 to the selection terminals 501 and 504 simultaneously and connect the common terminal 500 to the selection terminals 502 and 504 simultaneously. Also, for example, the switch circuit 50 can connect the common terminal 500 to the selection terminals 501 and 505 simultaneously and connect the common terminal 500 to the selection terminals 502 and 505 simultaneously. The switch circuit 50 is formed of, for example, a multi-connection switch circuit.

### 1.3. Implementation Example of the Filter 30

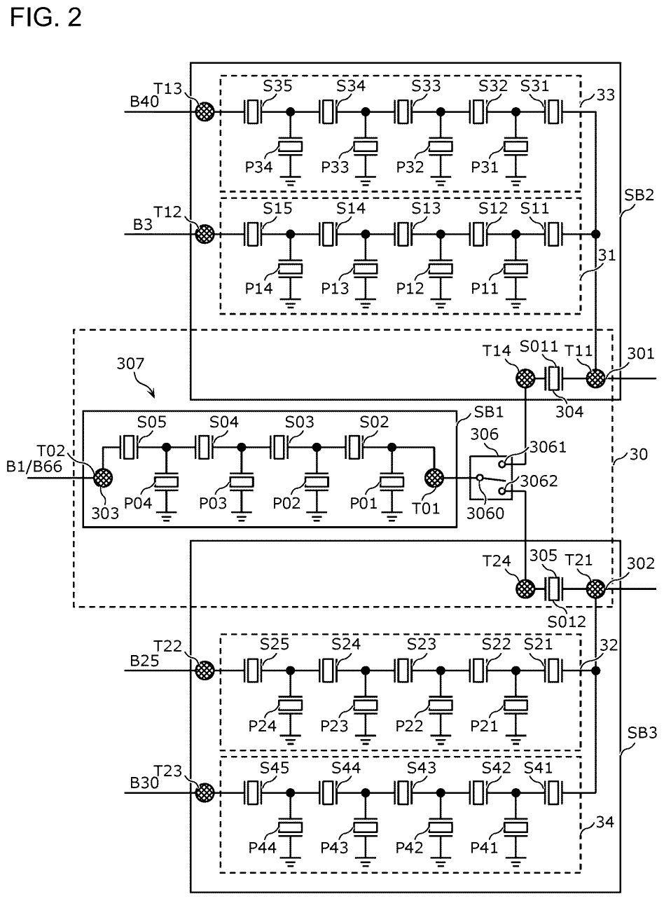

Next, an implementation example of the filter 30 is described with reference to FIG. 2. FIG. 2 is an implementation example of the filters 30 to 34 according to the present embodiment.

Note that FIG. 2 is an exemplary diagram, and the filters 30 to 34 may be implemented using any of various kinds of circuit implementation and circuit technology. Thus, the descriptions of the filters 30 to 34 provided below are not to be interpreted as limitative.

The filter 30 is divided into and implemented on a plurality of substrates SB1, SB2, and SB3. The substrates SB1, SB2, and SB3 include, for example, a piezoelectric body, and an acoustic wave resonator is formed by a functional electrode formed at the piezoelectric body.

Disposed at the substrate SB1 are a plurality of acoustic wave resonators S02, S03, S04, S05, P01, P02, P03, and P04 and external connection terminals T01 and T02.

The plurality of acoustic wave resonators S02 to S05 and P01 to P04 are an implementation example of the acoustic wave resonator 307. The plurality of acoustic wave resonators S02 to S05 and P01 to P04 are each formed of, for example, a bulk acoustic wave (BAW) resonator or a surface acoustic wave (SAW) resonator. The plurality of acoustic wave resonators S02 to S05 are connected in series on a signal path connecting the external connection terminals T01 and T02, and the plurality of acoustic wave resonators P01 to P04 are connected in parallel between the ground and the signal path connecting the external connection terminals T01 and T02. Note that the number of acoustic wave resonators included in the acoustic wave resonator 307 is not limited to eight. Also, the acoustic wave resonator 307 may include an inductor and/or a capacitor.

The external connection terminal T01 is connected to the switch circuit 306 outside the substrate SB1 and is connected to the acoustic wave resonator S02 inside the substrate SB1. The external connection terminal T02 is an implementation example of the output terminal 303 and is connected to the input end of the low-noise amplifier 20 outside the substrate SB1 and connected to the acoustic wave resonator S05 inside the substrates SB1. The external connection terminals T01 and T02 may be formed of, for example, a copper bump, a solder bump, or the like.

Disposed at the substrate SB2 are an acoustic wave resonator S011 and external connection terminals T11 and T14.

The acoustic wave resonator S011 is an implementation example of the series-arm resonator 304 and is formed of, for example, a BAW resonator or a SAW resonator. The acoustic wave resonator S011 is connected in series on a signal path connecting the external connection terminals T11 and T14.

The external connection terminal T11 is an implementation example of the input terminal 301 and is connected to the selection terminal 501 of the switch circuit 50 outside the substrate SB2 and connected to one end of the acoustic wave resonator S011 inside the substrate SB2. The external connection terminal T14 is connected to the selection terminal 3061 of the switch circuit 306 outside the substrate SB2 and connected to the other end of the acoustic wave resonator S011 inside the substrate SB2. The external connection terminals T11 and T14 may be formed of, for example, a copper bump, a solder bump, or the like.

Also disposed at the substrate SB2 are a plurality of acoustic wave resonators S11, S12, S13, S14, S15, P11, P12, P13, P14, S31, S32, S33, S34, S35, P31, P32, P33, and P34 and external connection terminals T12 and T13.

The plurality of acoustic wave resonators S11 to S15 and P11 to P14 are an implementation example of the filter 31. The plurality of acoustic wave resonators S11 to S15 and P11 to P14 are each formed of, for example, a BAW resonator or a SAW resonator. The plurality of acoustic wave resonators S11 to S15 are connected in series on a signal path connecting the external connection terminals T11 and T12, and the plurality of acoustic wave resonators P11 to P14 are connected in parallel between the ground and the signal path connecting the external connection terminals T11 and T12. Note that the number of acoustic wave resonators included in the filter 31 is not limited to nine. Also, the filter 31 may include an inductor and/or a capacitor.

A plurality of acoustic wave resonators S31 to S35 and P31 to P34 are an implementation example of the filter 33. The plurality of acoustic wave resonators S31 to S35 and P31 to P34 are each formed of, for example, a BAW resonator or a SAW resonator. The plurality of acoustic wave resonators S31 and S35 are connected in series on a signal path connecting the external connection terminals T11 and T13, and the plurality of acoustic wave resonators P31 to P34 are connected in parallel between the ground and the signal path connecting the external connection terminals T11 and T13. Note that the number of acoustic wave resonators included in the filter 33 is not limited to nine. Also, the filter 33 may include an inductor and/or a capacitor.

The external connection terminal T12 is connected to the input end of the low-noise amplifier 21 outside the substrate SB2 and connected to the acoustic wave resonator S15 inside the substrate SB2. The external connection terminal T13 is connected to the input end of the low-noise amplifier 23 outside the substrate SB2 and connected to the acoustic wave resonator S35 inside the substrate SB2. The external connection terminals T12 and T13 may be formed of, for example, a copper bump, a solder bump, or the like.

Disposed at the substrate SB3 are an acoustic wave resonator S012 and external connection terminals T21 and T24.

The acoustic wave resonator S012 is an implementation example of the series-arm resonator 305 and is formed of, for example, a BAW resonator or a SAW resonator. The acoustic wave resonator S012 is connected in series on a signal path connecting the external connection terminals T21 and T24.

The external connection terminal T21 is an implementation example of the input terminal 302 and is connected to the selection terminal 502 of the switch circuit 50 outside the substrate SB3 and connected to one end of the acoustic wave resonator S012 inside the substrate SB3. The external connection terminal T24 is connected to the selection terminal 3062 of the switch circuit 306 outside the substrate SB3 and connected to the other end of the acoustic wave resonator S012 inside the substrate SB3. The external connection terminals T21 and T24 may be formed of, for example, a copper bump, a solder bump, or the like.

Also disposed at the substrate SB3 are a plurality of acoustic wave resonators S21, S22, S23, S24, S25, P21, P22, P23, P24, S41, S42, S43, S44, S45, P41, P42, P43, and P44 and external connection terminals T22 and T23.

The plurality of acoustic wave resonators S21 to S25 and P21 to P24 are an implementation example of the filter 32. The plurality of acoustic wave resonators S21 to S25 and P21 to P24 are each formed of, for example, a BAW resonator or a SAW resonator. The plurality of acoustic wave resonators S21 to S25 are connected in series on a signal path connecting the external connection terminals T21 and T22, and the plurality of acoustic wave resonators P21 to P24 are connected in parallel between the ground and the signal path connecting the external connection terminals T21 and T22. Note that the number of acoustic wave resonators included in the filter 32 is not limited to nine. Also, the filter 32 may include an inductor and/or a capacitor.

The plurality of acoustic wave resonators S41 to S45 and P41 to P44 are an implementation example of the filter 34. The plurality of acoustic wave resonators S41 to S45 and P41 to P44 are each formed of, for example, a BAW resonator or a SAW resonator. The plurality of acoustic wave resonators S41 to S45 are connected in series on a signal path connecting the external connection terminals T21 and T23, and the plurality of acoustic wave resonators P41 to P44 are connected in parallel between the ground and the signal path connecting the external connection terminals T21 and T23. Note that the number of acoustic wave resonators included in the filter 34 is not limited to nine. Also, the filter 34 may include an inductor and/or a capacitor.

The external connection terminal T22 is connected to the input end of the low-noise amplifier 22 outside the substrate SB3 and connected to the acoustic wave resonator S25 inside the substrate SB3. The external connection terminal T23 is connected to the input end of the low-noise amplifier 24 outside the substrate SB3 and connected to the acoustic wave resonator S45 inside the substrate SB3. The external connection terminals T22 and T23 may be formed of, for example, a copper bump, a solder bump, or the like.

Although the filters 31 and 33 are implemented on the same substrate SB2 in FIG. 2, they may be implemented on separate substrates. Similarly, the filters 32 and 34 may be implemented on separate substrates.

### 1.4. Summary

As described above, the filter 30 according to the present embodiment is the filter 30 having a pass band including a reception band which is a first band and a reception band which is a second band, the filter 30 having the input terminals 301 and 302, the output terminal 303, the switch circuit 306 including the common terminal 3060 and the selection terminals 3061 and 3062, the series-arm resonator 304 connected between the selection terminal 3061 and the input terminal 301, the series-arm resonator 305 connected between the selection terminal 3062 and the input terminal 302, and the acoustic wave resonator 307 connected between the common terminal 3060 and the output terminal 303.

Thus, both of the reception band which is the first band and the reception band which is the second band can be supported with the single filter 30. Then, compared to a case where separate filters are prepared for the reception band which is the first band and the reception band which is the second band, the number of filters can be decreased. Further, the two series-arm resonators 304 and 305 respectively connected to the two input terminals 301 and 302 can be selectively connected to the acoustic wave resonator 307 by the switch circuit 306. Thus, compared to a case where two acoustic wave resonators are connected to the two respective input terminals 301 and 302, the number of acoustic wave resonators can be decreased, and the filter 30 can be reduced in size. Also, the two series-arm resonators 304 and 305 can be connected respectively to the selection terminals 501 and 502 of the switch circuit 50 via the input terminals 301 and 302. Thus, it is possible to facilitate impedance adjustment for the other band capable of simultaneous communication with the first or second band (e.g., the third or fourth band) when the filter 30 is seen from the selection terminals 501 and 502 of the switch circuit 50, and therefore to reduce signal loss in the other band upon simultaneous reception of a signal in the first band and a signal in the other band.

In addition, for example, in the filter 30 according to the present embodiment, the resonant frequency of the series-arm resonator 304 may be included in the pass band of the filter 30.

This enables the series-arm resonator 304 to be used form the pass band of the filter 30, making it possible to decrease the number of resonators compared to a case where the series-arm resonator 304 is used simply for impedance adjustment.

Also, for example, in the filter 30 according to the present embodiment, the resonant frequency of the series-arm resonator 305 may be included in the pass band of the filter 30.

This enables the series-arm resonator 305 to be used to form the pass band of the filter 30, making it possible to decrease the number of resonators compared to a case where the series-arm resonator 305 is used simply for impedance adjustment.

In addition, the high frequency circuit 1 according to the present embodiment has the filter 30, the filter 31 having a pass band including a reception band which is a third band, the filter 32 having a pass band including a reception band which is a fourth band, and the switch circuit 50 including the common terminal 500 connected to the antenna connection terminal 100 and the selection terminals 501 and 502. The selection terminal 501 is connected to the input terminal 301 of the filter 30 and also connected to the filter 31, the selection terminal 502 is connected to the input terminal 302 of the filter 30 and also connected to the filter 32, a combination of the first band and the third band is a band combination capable of simultaneous communication, and a combination of the second band and the fourth band is a band combination capable of simultaneous communication.

Thus, both of the reception band which is the first band and the reception band which is the second band can be supported with the single filter 30. Then, compared to a case where separate filters are prepared for the reception band which is the first band and the reception band which is the second band, the number of filters can be decreased. Further, the two series-arm resonators 304 and 305 connected respectively to the two input terminals 301 and 302 can be selectively connected to the acoustic wave resonator 307 by the switch circuit 306. Thus, compared to a case where two acoustic wave resonators are connected to the two respective input terminals 301 and 302, the number of acoustic wave resonators can be decreased, and the filter 30 can be reduced in size. Also, the two series-arm resonators 304 and 305 can be connected respectively to the selection terminals 501 and 502 of the switch circuit 50 via the input terminals 301 and 302. Thus, it is possible to facilitate impedance adjustment for the third band when the filter 30 is seen from the selection terminal 501 of the switch circuit 50, and therefore to reduce signal loss in the third band upon simultaneous reception of a signal in the first band and a signal in the third band. Similarly, it is possible to facilitate impedance adjustment for the fourth band when the filter 30 is seen from the selection terminal 502 of the switch circuit 50, and therefore to reduce signal loss in the fourth band upon simultaneous reception of a signal in the second band and a signal in the fourth band.

In addition, the high frequency circuit 1 according to the present embodiment may further have the filter 33 connected to the selection terminal 501 and having a pass band including a reception band which is a fifth band and the filter 34 connected to the selection terminal 502 and having a pass band including a reception band which is a sixth band. A combination of the first band and the fifth band may be a band combination capable of simultaneous communication, and a combination of the second band and the sixth band may be a band combination capable of simultaneous communication.

It is accordingly possible to facilitate impedance adjustment for the fifth band when the filter 30 is seen from the selection terminal 501 of the switch circuit 50, and therefore to reduce signal loss in the fifth band upon simultaneous reception of a signal in the first band and a signal in the fifth band. Similarly, it is possible to facilitate impedance adjustment for the sixth band when the filter 30 is seen from the selection terminal 502 of the switch circuit 50, and therefore to reduce signal loss in the sixth band upon simultaneous reception of a signal in the second band and a signal in the sixth band.

In addition, in the high frequency circuit 1 according to the present embodiment, the switch circuit 50 may further include the selection terminal 503, and the high frequency circuit 1 may further have the filter 35 connected to the selection terminal 503 and having a pass band including a reception band which is a seventh band and the filter 36 connected to the selection terminal 503 and having a pass band including a reception band which is an eighth band. A combination of the seventh band and the eighth band may be a band combination capable of simultaneous communication.

It is accordingly possible to support simultaneous reception of signals in the seventh band and the eighth band.

In addition, in the high frequency circuit 1 according to the present embodiment, the switch circuit 50 may further include the selection terminal 504, and the high frequency circuit 1 may further have the filter 37 connected to the selection terminal 504 and having a pass band including a reception band which is a ninth band. A combination of the first band and the ninth band and a combination of the second band and the ninth band may both be a band combination capable of simultaneous communication.

It is accordingly possible to support simultaneous reception of a signal in the first or second band and a signal in the ninth band.

In addition, in the high frequency circuit 1 according to the present embodiment, the switch circuit 50 may further include the selection terminal 505, the high frequency circuit 1 may further have the filter 38 connected to the selection terminal 505 and having a pass band including a reception band which is a tenth band, and a combination of the first band and the tenth band and a combination of the second band and the tenth band may both be a band combination capable of simultaneous communication.

It is accordingly possible to support simultaneous reception of a signal in the first or second band and a signal in the tenth band.

In addition, in the high frequency circuit 1 according to the present embodiment, the first band may be Band 1 for LTE or n1 for 5G NR, the second band may be Band 66 for LTE or n66 for 5G NR, the third band may be Band 3 for LTE or n3 for 5G NR, the fourth band may be Band 25 for LTE or n25 for 5G NR, the fifth band may be Band 40 for LTE or n40 for 5G NR, the sixth band may be Band 30 for LTE or n30 for 5G NR, the seventh band may be Band 34 for LTE or n34 for 5G NR, the eighth band may be Band 39 for LTE or n39 for 5G NR, the ninth band may be Band 7 for LTE or n7 for 5G NR, and the tenth band may be Band 41 for LTE or n41 for 5G NR.

It is accordingly possible to support 5G NR and/or LTE.

### Embodiment 2

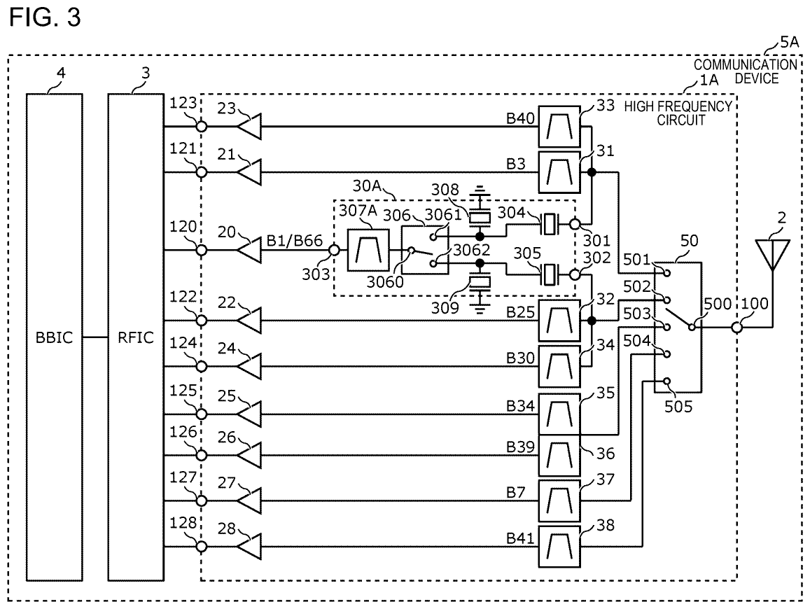

Next, Embodiment 2 is described. The present embodiment differs from Embodiment 1 mainly in that, in addition to the series-arm resonators, parallel-arm resonators are switchably connected to acoustic wave resonators. With reference to FIG. 3, the following describes the present embodiment, focusing mainly on differences from Embodiment 1 described above.

FIG. 3 is a circuit configuration diagram of a communication device 5A according to the present embodiment. Note that FIG. 3 is an exemplary circuit configuration, and the communication device 5A may be implemented using any of various kinds of circuit implementation and circuit technology. Thus, the descriptions of the communication device 5A provided below are not to be interpreted as limitative.

Note that in FIG. 3, like in FIG. 1, numbers with the letter B that are written next to filters denote numbers identifying frequency bands in LTE and/or 5G NR. Note that the frequency bands shown in FIG. 3 are presented as examples to facilitate understanding by those skilled in the art, and the frequency bands corresponding to the respective filters are not limited to what is shown in FIG. 3.

### 2.1. Circuit Configuration of the Communication Device 5A

First, the circuit configuration of the communication device 5A according to the present embodiment is described with reference to FIG. 3. The communication device 5A has a high frequency circuit 1A, the antenna 2, the RFIC 3, and the BBIC 4. In other words, the communication device 5A is the same as the communication device 5 according to Embodiment 1 except for having the high frequency circuit 1A in place of the high frequency circuit 1.

### 2.2. Circuit Configuration of the High Frequency Circuit 1A

Next, the circuit configuration of the high frequency circuit 1A according to the present embodiment is described with reference to FIG. 3. The high frequency circuit 1A has the low-noise amplifiers 20 to 28, filters 30A, 31, 32, 33, 34, 35, 36, 37, and 38, the switch circuit 50, the antenna connection terminal 100, and the high frequency output terminals 120, 121, 122, 123, 124, 125, 126, 127, and 128. Thus, the high frequency circuit 1A is the same as the high frequency circuit 1 according to Embodiment 1 except for having the filter 30A in place of the filter 30.

The filter 30A is an acoustic wave filter and is a band pass filter having a pass band including a reception band which is a first band (B1) and a reception band which is a second band (B66). One end of the filter 30A is connected to the input end of the low-noise amplifier 20, and the other end of the filter 30A is connected to the selection terminals 501 and 502 of the switch circuit 50. Specifically, the filter 30A has the input terminals 301 and 302, the output terminal 303, the series-arm resonators 304 and 305, the switch circuit 306, an acoustic wave resonator 307A, and parallel-arm resonators 308 and 309.

The parallel-arm resonator 308 is an example of the first parallel-arm acoustic wave resonator and is connected between the ground and a path connecting the input terminal 301 and the selection terminal 3061. Specifically, the parallel-arm resonator 308 corresponds to the acoustic wave resonator P01 included in the acoustic wave resonator 307 in Embodiment 1.

The parallel-arm resonator 309 is an example of the second parallel-arm acoustic wave resonator and is connected between the ground and a path connecting the input terminal 302 and the selection terminal 3062. Specifically, the parallel-arm resonator 309 corresponds to the acoustic wave resonator P01 included in the acoustic wave resonator 307 of Embodiment 1.

The acoustic wave resonator 307A is connected between the common terminal 3060 of the switch circuit 306 and the output terminal 303 of the filter 30A. The acoustic wave resonator 307A is, via the switch circuit 306, selectively connected to a set of the series-arm resonator 304 and the parallel-arm resonator 308 and a set of the series-arm resonator 305 and the parallel-arm resonator 309. The resonant frequencies of the series-arm resonators 304 and 305 and the anti-resonant frequencies of the parallel-arm resonators 308 and 309 may be included in the pass band of the filter 30A, and the pass band of the filter 30A may be formed by them. Although an implementation example of the acoustic wave resonator 307A is not depicted or described, the acoustic wave resonator 307A corresponds to the acoustic wave resonator 307 without necessarily the acoustic wave resonator P01 in FIG. 2. Also, the acoustic wave resonator P01 is disposed in each of the substrates SB2 and SB3.

### 2.3. Summary

As described above, the filter 30A according to the present embodiment may further have the parallel-arm resonator 308 connected between the ground and the path connecting the input terminal 301 and the selection terminal 3061 and the parallel-arm resonator 309 connected between the ground and the path connecting the input terminal 302 and the selection terminal 3062.

Thus, in addition to the series-arm resonators 304 and 305, the parallel-arm resonators 308 and 309 are connected to the selection terminals 501 and 502 of the switch circuit 50 via the input terminals 301 and 302, respectively. Thus, it is possible to further reduce impedance drift in the other band capable of simultaneous communication when the filter 30A is seen from the selection terminals 501 and 502 of the switch circuit 50, and therefore to further reduce signal loss in a certain band upon simultaneous reception of a signal in the first band and a signal in the certain band (e.g., the third band) and simultaneous reception of a signal in the second band and a signal in the certain band (e.g., the fourth band).

### Embodiment 3

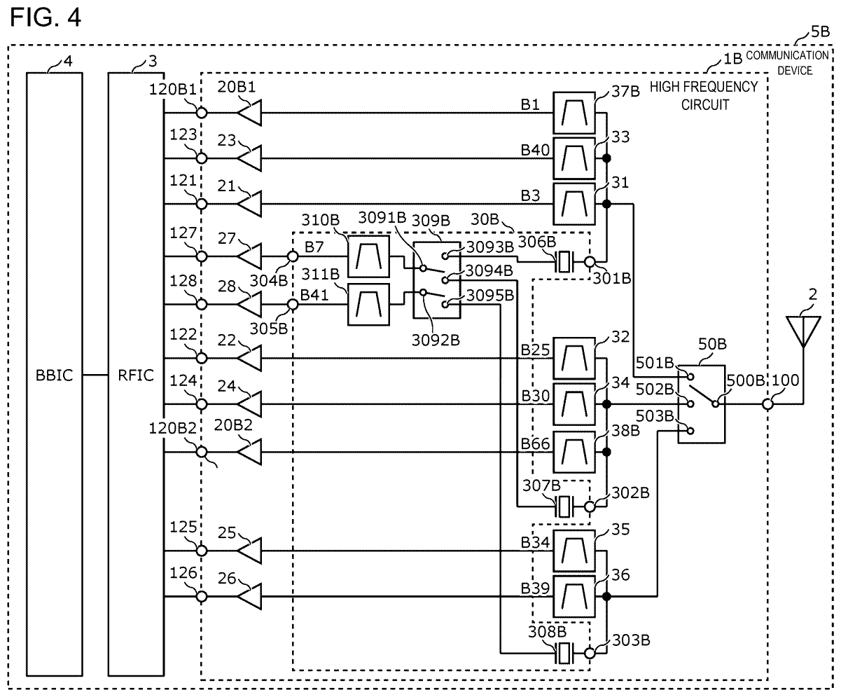

Next, Embodiment 3 is described. The present embodiment differs from Embodiment 1 mainly in that a first pass band including a reception band which is a first band and a second pass band including a reception band which is a second band are switchable. With reference to FIG. 4, the following describes the present embodiment, focusing mainly on differences from Embodiment 1 described above.

FIG. 4 is a circuit configuration diagram of a communication device 5B according to the present embodiment. Note that FIG. 4 is an exemplary circuit configuration, and the communication device 5B may be implemented using any of various kinds of circuit implementation and circuit technology. Thus, the descriptions of the communication device 5B provided below are not to be interpreted as limitative.

Note that in FIG. 4, like in FIG. 1, numbers with the letter B that are written next to filters denote numbers identifying frequency bands in LTE and/or 5G NR. The frequency bands shown in FIG. 4 are presented as examples to facilitate understanding by those skilled in the art, and the frequency bands corresponding to the respective filters are not limited to what is shown in FIG. 4.

### 3.1. Circuit Configuration of the Communication Device 5B

First, the circuit configuration of the communication device 5B according to the present embodiment is described with reference to FIG. 4. The communication device 5B has a high frequency circuit 1B, the antenna 2, the RFIC 3, and the BBIC 4. In other words, the communication device 5B is the same as the communication device 5 according to Embodiment 1 except for having the high frequency circuit 1B in place of the high frequency circuit 1.

### 3.2. Circuit Configuration of the High Frequency Circuit 1B

Next, the circuit configuration of the high frequency circuit 1B according to the present embodiment is described with reference to FIG. 4. The high frequency circuit 1B has low-noise amplifiers 20B1, 20B2, 21, 22, 23, 24, 25, 26, 27, and 28, filters 30B, 31, 32, 33, 34, 35, 36, 37B, and 38B, and a switch circuit 50B, the antenna connection terminal 100, high frequency output terminals 120B1, 120B2, 121, 122, 123, 124, 125, 126, 127, and 128.

The high frequency output terminals 120B1 and 120B2 are each an external connection terminal of the high frequency circuit 1B and are connected to the RFIC 3 outside the high frequency circuit 1B. Also, the high frequency output terminals 120B1 and 120B2 are connected to the output ends of the low-noise amplifiers 20B1 and 20B2, respectively, inside the high frequency circuit 1. Thus, the high frequency circuit 1B can supply signals received in the ninth and tenth bands and amplified by the low-noise amplifiers 20B1 and 20B2 to the RFIC 3 via the high frequency output terminals 120B1 and 120B2, respectively.

The input ends of the low-noise amplifiers 20B1 and 20B2 are connected to the filters 37B and 38B, respectively, and the output ends of the low-noise amplifiers 20B1 and 20B2 are connected to the high frequency output terminals 120B1 and 120B2, respectively. Thus, the low-noise amplifiers 20B1 and 20B2 can amplify signals received in the ninth and tenth bands, respectively.

The low-noise amplifiers 20B1 and 20B2 can be formed of FETs and can be manufactured using a semiconductor material. For example, single-crystal silicon, GaN, or SiC can be used as the semiconductor material. Note that amplification transistors for the low-noise amplifiers 20B1 and 20B2 are not limited to FETs. For example, some or all of the low-noise amplifiers 20B1 and 20B2 may be formed of a bipolar transistor.

Note that some or all of the low-noise amplifiers 20B1 and 20B2 may be not included in the high frequency circuit 1B. In this case, some or all of the low-noise amplifiers 20B1 and 20B2 may be connected between the RFIC 3 and the high frequency output terminals 120B1 and 120B2 or may be included in the RFIC 3.

The filter 30B is an acoustic wave filter and is a variable band pass filter switchable between a first pass band including a reception band which is a first band (B7) and a second pass band including a reception band which is a second band (B41). One end of the filter 30B is connected to the input ends of the low-noise amplifiers 27 and 28, and the other end of the filter 30B is connected to selection terminals 501B, 502B, and 503B of the switch circuit 50B.

In the present embodiment, as the first band, Band 7 for LTE or n7 for 5G NR can be used, but the first band is not limited to these. Also, as the second band, Band 41 for LTE or n41 for 5G NR can be used, but the second band is not limited to these.

The filter 30B has input terminals 301B, 302B, and 303B, output terminals 304B and 305B, series-arm resonators 306B, 307B, and 308B, a switch circuit 309B, and acoustic wave resonators 310B and 311B.

The input terminal 301B is an example of the first input terminal and is connected to the selection terminal 501B of the switch circuit 50B outside the filter 30B and connected to the series-arm resonator 306B inside the filter 30B.

The input terminal 302B is an example of the second input terminal and is connected to the selection terminal 502B of the switch circuit 50B outside the filter 30B and connected to the series-arm resonator 307B inside the filter 30B.

The input terminal 303B is an example of the third input terminal and is connected to the selection terminal 503B of the switch circuit 50B outside the filter 30B and connected to the series-arm resonator 308B inside the filter 30B.

The output terminal 304B is connected to the input end of the low-noise amplifier 27 outside the filter 30B and connected to the acoustic wave resonator 310B inside the filter 30B.

The output terminal 305B is connected to the input end of the low-noise amplifier 28 outside the filter 30B and connected to the acoustic wave resonator 311B inside the filter 30B.

The series-arm resonator 306B is an example of the first series-arm acoustic wave resonator and is connected between the input terminal 301B and the switch circuit 309B.

The series-arm resonator 307B is an example of the second series-arm acoustic wave resonator and is connected between the input terminal 302B and the switch circuit 309B.

The series-arm resonator 308B is an example of the third series-arm acoustic wave resonator and is connected between the input terminal 303B and the switch circuit 309B.

The switch circuit 309B is an example of the first switch circuit and is connected between the series-arm resonators 306B, 307B, and 308B and the acoustic wave resonators 310B and 311B. The switch circuit 309B includes common terminals 3091B and 3092B and selection terminals 3093B, 3094B, and 3095B. The common terminal 3091B is an example of the first common terminal and is connected to the acoustic wave resonator 310B. The common terminal 3092B is an example of the second common terminal and is connected to the acoustic wave resonator 311B. The selection terminal 3093B is an example of the first selection terminal and is connected to the series-arm resonator 306B. The selection terminal 3094B is an example of the second selection terminal and is connected to the series-arm resonator 307B. The selection terminal 3095B is an example of the third selection terminal and is connected to the series-arm resonator 308B.

In such a connection configuration, the switch circuit 309B can connect the common terminals 3091B and 3092B to the selection terminals 3093B, 3094B, and 3095B based on, e.g., a control signal from the RFIC 3. The switch circuit 309B is formed of, for example, a double-pole, triple-throw (DP3T) switch circuit.

The acoustic wave resonator 310B is an example of the first acoustic wave resonator and is connected between the output terminal 304B and the common terminal 3091B of the switch circuit 309B. The acoustic wave resonator 310B is selectively connected to the series-arm resonators 306B, 307B, and 308B via the switch circuit 309B. The resonant frequencies of the series-arm resonators 306B, 307B, and 308B may be included in the first pass band, and the first pass band of the filter 30B may be formed by them.

The acoustic wave resonator 311B is an example of the second acoustic wave resonator and is connected between the output terminal 305B and the common terminal 3092B of the switch circuit 309B. The acoustic wave resonator 311B is selectively connected to the series-arm resonators 306B, 307B, and 308B via the switch circuit 309B. The resonant frequencies of the series-arm resonators 306B, 307B, and 308B may be included in the second pass band, and the second pass band of the filter 30B may be formed by them.

The filter 31 is an example of the first filter and is a band pass filter having a pass band including a reception band which is a third band (B3). One end of the filter 31 is connected to the input end of the low-noise amplifier 21, and the other end of the filter 31 is connected to the selection terminal 501B of the switch circuit 50B.

The filter 32 is an example of the second filter and is a band pass filter having a pass band including a reception band which is a fourth band (B25). One end of the filter 32 is connected to the input end of the low-noise amplifier 22, and the other end of the filter 32 is connected to the selection terminal 502B of the switch circuit 50B.

The filter 33 is an example of the fourth filter and is a band pass filter having a pass band including a reception band which is a sixth band (B40). One end of the filter 33 is connected to the input end of the low-noise amplifier 23, and the other end of the filter 33 is connected to the selection terminal 501B of the switch circuit 50B. Note that the filter 33 does not have to be included in the high frequency circuit 1B.

The filter 34 is an example of the fifth filter and is a band pass filter having a pass band including a reception band which is a seventh band (B30). One end of the filter 34 is connected to the input end of the low-noise amplifier 24, and the other end of the filter 34 is connected to the selection terminal 502B of the switch circuit 50B. Note that the filter 34 does not have to be included in the high frequency circuit 1B.

The filter 35 is an example of the third filter and is a band pass filter having a pass band including a reception band which is a fifth band (B34). One end of the filter 35 is connected to the input end of the low-noise amplifier 25, and the other end of the filter 35 is connected to the selection terminal 503B of the switch circuit 50B.

The filter 36 is an example of the sixth filter and is a band pass filter having a pass band including a reception band which is an eighth band (B39). One end of the filter 36 is connected to the input end of the low-noise amplifier 26, and the other end of the filter 36 is connected to the selection terminal 503B of the switch circuit 50B. Note that the filter 36 does not have to be included in the high frequency circuit 1B.

The filter 37B is an example of the seventh filter and is a band pass filter having a pass band including a reception band which is a ninth band (B1). One end of the filter 37B is connected to the input end of the low-noise amplifier 20B1, and the other end of the filter 37B is connected to the selection terminal 501B of the switch circuit 50B. Note that the filter 37B does not have to be included in the high frequency circuit 1B.

The filter 38B is an example of the eighth filter and is a band pass filter having a pass band including a reception band which is a tenth band (B66). One end of the filter 38B is connected to the input end of the low-noise amplifier 20B2, and the other end of the filter 38B is connected to the selection terminal 502B of the switch circuit 50B. Note that the filter 38B does not have to be included in the high frequency circuit 1B.

In the present embodiment, at least one of a combination of the first band and the third band and a combination of the second band and the third band is a band combination capable of simultaneous communication. As such a third band, Band 3 for LTE or n3 for 5G NR can be used, but the third band is not limited to these.

Also, at least one of a combination of the first band and the fourth band and a combination of the second band and the fourth band is a band combination capable of simultaneous communication. As such a fourth band, Band 25 for LTE or n25 for 5G NR can be used, but the fourth band is not limited to these.

Also, at least one of a combination of the first band and the fifth band and a combination of the second band and the fifth band is a band combination capable of simultaneous communication. As such a fifth band, Band 40 for LTE or n40 for 5G NR can be used, but the fifth band is not limited to these.

Also, at least one of a combination of the first band and the sixth band and a combination of the second band and the sixth band is a band combination capable of simultaneous communication. As such a sixth band, Band 30 for LTE or n30 for 5G NR can be used, but the sixth band is not limited to these.

Also, at least one of a combination of the first band and the seventh band and a combination of the second band and the seventh band is a band combination capable of simultaneous communication. As such a seventh band, Band 34 for LTE or n34 for 5G NR can be used, but the seventh band is not limited to these.

Also, at least one of a combination of the first band and the eighth band and a combination of the second band and the eighth band is a band combination capable of simultaneous communication. As such an eighth band, Band 39 for LTE or n39 for 5G NR can be used, but the eighth band is not limited to these.

Also, at least one of a combination of the first band and the ninth band and a combination of the second band and the ninth band is a band combination capable of simultaneous communication. As such a ninth band, Band 1 for LTE or n1 for 5G NR can be used, but the ninth band is not limited to these.

Also, at least one of a combination of the first band and the tenth band and a combination of the second band and the tenth band is a band combination capable of simultaneous communication. As such a tenth band, Band 66 for LTE or n66 for 5G NR can be used, but the tenth band is not limited to these.

The switch circuit 50B is an example of the second switch circuit and is connected between the antenna connection terminal 100 and the filters 30B, 31 to 36, 37B, and 38B. Specifically, the switch circuit 50B includes a common terminal 500B and the selection terminals 501B, 502B, and 503B. The common terminal 500B is an example of the third common terminal and is connected to the antenna connection terminal 100. The selection terminal 501B is an example of the fourth selection terminal and is connected to the filters 30B, 31, 33, and 37B. The selection terminal 502B is an example of the fifth selection terminal and is connected to the filters 30B, 32, 34, and 38B. The selection terminal 503B is an example of the sixth selection terminal and is connected to the filters 30B, 35, and 36.

In such a connection configuration, the switch circuit 50B can connect the common terminal 500B exclusively to one of the selection terminals 501B to 503B based on, e.g., a control signal from the RFIC 3. The switch circuit 50B is formed of, for example, a single-pole, triple-throw (SP3T) switch circuit.

### 3.3. Summary

As described above, the filter 30B according to the present embodiment is the filter 30B switchable between a first pass band including a reception band which is a first band and a second pass band including a reception band which is a second band, the filter 30B having the input terminals 301B, 302B, and 303B, the output terminals 304B and 305B, the switch circuit 309B including the common terminals 3091B and 3092B and the selection terminals 3093B, 3094B, and 3095B, the series-arm resonator 306B connected between the selection terminal 3093B and the input terminal 301B, the series-arm resonator 307B connected between the selection terminal 3094B and the input terminal 302B, the series-arm resonator 308B connected between the selection terminal 3095B and the input terminal 303B, the acoustic wave resonator 310B connected between the common terminal 3091B and the output terminal 304B, and the acoustic wave resonator 311B connected between the common terminal 3092B and the output terminal 305B.

Because the input terminals 301B, 302B, and 303B of the filter 30B can accordingly be connected to the three respective selection terminals to which other filters are connected, the number of selection terminals of the switch circuit 50B can be decreased. Thus, the off capacitance of the switch circuit 50B can be reduced. Also, the series-arm resonators 306B, 307B, and 308B can be connected to the selection terminals 501B, 502B, and 503B of the switch circuit 50B via the input terminals 301B, 302B, and 303B, respectively. Thus, it is possible to facilitate impedance adjustment for the other band capable of simultaneous communication with the first or second band when the filter 30B is seen from the selection terminals of the switch circuit 50B, and therefore to reduce signal loss in the other band upon simultaneous reception of a signal in the first or second band and a signal in the other band (e.g., the third, fourth, or fifth band).

Also, for example, in the filter 30B according to the present embodiment, the resonant frequency of the series-arm resonator 306B may be included in the first pass band and the second pass band of the filter 30B.

This allows the series-arm resonator 306B to be used to form the pass band of the filter 30B, and the number of resonators can be decreased compared to a case where the series-arm resonator 306B is used simply for impedance adjustment.

Also, for example, in the filter 30B according to the present embodiment, the resonant frequency of the series-arm resonator 307B may be included in the first pass band and the second pass band of the filter 30B.

This allows the series-arm resonator 307B to be used to form the pass band of the filter 30B, and the number of resonators can be decreased compared to a case where the series-arm resonator 307B is used simply for impedance adjustment.

Also, for example, in the filter 30B according to the present embodiment, the resonant frequency of the series-arm resonator 308B may be included in the first pass band and the second pass band of the filter 30B.

This allows the series-arm resonator 308B to be used to form the pass band of the filter 30B, and the number of resonators can be decreased compared to a case where the series-arm resonator 308B is used simply for impedance adjustment.

Also, the high frequency circuit 1B according to the present embodiment has the filter 30B, the filter 31 having a pass band including a reception band which is a third band, the filter 32 having a pass band including a reception band which is a fourth band, the filter 35 having a pass band including a reception band which is a fifth band, and the switch circuit 50B including the common terminal 500B connected to the antenna connection terminal 100 and the selection terminals 501B, 502B, and 503B. The selection terminal 501B is connected to the input terminal 301B of the filter 30B and also connected to the filter 31, the selection terminal 502B is connected to the input terminal 302B of the filter 30B and also connected to the filter 32, the selection terminal 503B is connected to the input terminal 303B of the filter 30B and also connected to the filter 35. At least one of a combination of the first band and the third band and a combination of the second band and the third band is a band combination capable of simultaneous communication, at least one of a combination of the first band and the fourth band and a combination of the second band and the fourth band is a band combination capable of simultaneous communication, and at least one of a combination of the first band and the fifth band and a combination of the second band and the fifth band is a band combination capable of simultaneous communication.

Because the three input terminals 301B, 302B, and 303B of the filter 30B are thus respectively connected to the three selection terminals 501B, 502B, and 503B to which the filters 31, 32, and 35 are connected, the selection terminals to which the filters 37 and 38 are connected in Embodiment 1 are omitted. Thus, the number of selection terminals of the switch circuit 50B can be reduced, and the off capacitance of the switch circuit 50B can be reduced. Also, the series-arm resonators 306B, 307B, and 308B are connected to the selection terminals 501B, 502B, and 503B of the switch circuit 50B via the input terminals 301B, 302B, and 303B, respectively. Thus, it is possible to facilitate impedance adjustment for the third, fourth, and fifth bands when the filter 30B is seen from the selection terminals 501B, 502B, and 503B of the switch circuit 50B, and therefore to reduce signal loss in the third, fourth, and fifth bands upon simultaneous reception of a signal in the first or second band and a signal in each of the third, fourth, and fifth bands.

Also, for example, the high frequency circuit 1B according to the present embodiment may further have the filter 33 connected to the selection terminal 501B and having a pass band including a reception band which is a sixth band, the filter 34 connected to the selection terminal 502B and having a pass band including a reception band which is a seventh band, and the filter 36 connected to the selection terminal 503B and having a pass band including a reception band which is an eighth band. At least one of a combination of the first band and the sixth band and a combination of the second band and the sixth band may be a band combination capable of simultaneous communication, at least one of a combination of the first band and the seventh band and a combination of the second band and the seventh band may be a band combination capable of simultaneous communication, and at least one of a combination of the first band and the eighth band and a combination of the second band and the eighth band may be a band combination capable of simultaneous communication.

It is accordingly possible to facilitate impedance adjustment for the sixth, seventh, and eighth bands when the filter 30B is seen from the selection terminals 501B, 502B, and 503B of the switch circuit 50B, and therefore to reduce signal loss in the sixth, seventh, and eighth bands upon simultaneous reception of a signal in the first or second band and a signal in each of the sixth, seventh, and eighth bands.

Also, for example, the high frequency circuit 1B according to the present embodiment may further have the filter 37B connected to the selection terminal 501B and having a pass band including a reception band which is a ninth band and the filter 38B connected to the selection terminal 502B and having a pass band including a reception band which is a tenth band. At least one of a combination of the first band and the ninth band and a combination of the second band and the ninth band may be a band combination capable of simultaneous communication, and at least one of a combination of the first band and the tenth band and a combination of the second band and the tenth band may be a band combination capable of simultaneous communication.

It is accordingly possible to facilitate impedance adjustment for the ninth and tenth bands when the filter 30B is seen from the selection terminals 501B and 502B of the switch circuit 50B, and therefore to reduce signal loss in the ninth and tenth bands upon simultaneous reception of a signal in the first or second band and a signal in each of the ninth and tenth bands.

Also, for example, in the high frequency circuit 1B according to the present embodiment, the first band may be Band 7 for LTE or n7 for 5G NR, the second band may be Band 41 for LTE or n41 for 5G NR, the third band may be Band 3 for LTE or n3 for 5G NR, the fourth band may be Band 25 for LTE or n25 for 5G NR, the fifth band may be Band 34 for LTE or n34 for 5G NR, the sixth band may be Band 40 for LTE or n40 for 5G NR, the seventh band may be Band 30 for LTE or n30 for 5G NR, the eighth band may be Band 39 for LTE or n39 for 5G NR, the ninth band may be Band 1 for LTE or n1 for 5G NR, and the tenth band may be Band 66 for LTE or n66 for 5G NR.

It is accordingly possible to support 5G NR and/or LTE.

### Embodiment 4

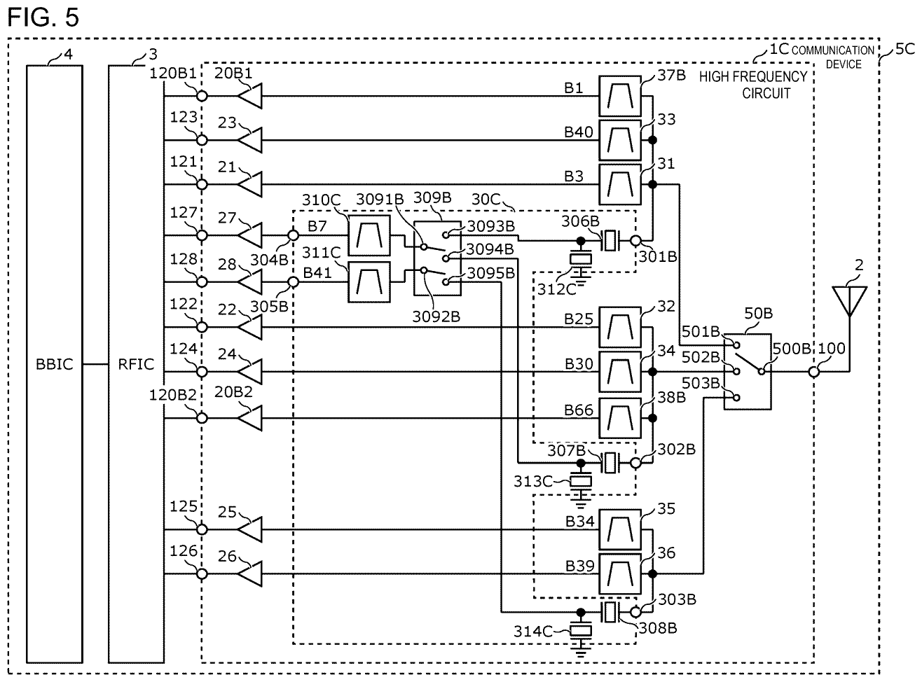

Next, Embodiment 4 is described. The present embodiment differs from Embodiment 3 described above mainly in that in addition to the series-arm resonators, parallel-arm resonators are switchably connected to acoustic wave resonators. With reference to FIG. 5, the following describes the present embodiment, focusing mainly on differences from Embodiment 3 described above.

FIG. 5 is a circuit configuration diagram of a communication device 5C according to the present embodiment. Note that FIG. 5 is an exemplary circuit configuration, and the communication device 5C may be implemented using any of various kinds of circuit implementation and circuit technology. Thus, the descriptions of the communication device 5C provided below are not to be interpreted as limitative.

Note that in FIG. 5, like in FIG. 1, numbers with the letter B that are written next to filters denote numbers identifying frequency bands in LTE and/or 5G NR. The frequency bands shown in FIG. 5 are presented as examples to facilitate understanding by those skilled in the art, and the frequency bands corresponding to the respective filters are not limited to what is shown in FIG. 5.

### 4.1. Circuit Configuration of the Communication Device 5C

First, the circuit configuration of the communication device 5C according to the present embodiment is described with reference to FIG. 5. The communication device 5C has a high frequency circuit 1C, the antenna 2, the RFIC 3, and the BBIC 4. In other words, the communication device 5C is the same as the communication device 5B according to Embodiment 3 except for having the high frequency circuit 1C in place of the high frequency circuit 1B.

### 4.2. Circuit Configuration of the High Frequency Circuit 1C

Next, the circuit configuration of the high frequency circuit 1C according to the present embodiment is described with reference to FIG. 5. The high frequency circuit 1C has low-noise amplifiers 20B1, 20B2, 21, 22, 23, 24, 25, 26, 27, and 28, filters 30C, 31, 32, 33, 34, 35, 36, 37B, and 38B, the switch circuit 50B, the antenna connection terminal 100, and the high frequency output terminals 120B1, 120B2, 121, 122, 123, 124, 125, 126, 127, and 128. In other words, the high frequency circuit 1C is the same as the high frequency circuit 1B according to Embodiment 3 except for having the filter 30C in place of filter 30B.

The filter 30C is an acoustic wave filter and is a variable band pass filter switchable between a first pass band including a reception band which is a first band (B7) and a second pass band including a reception band which is a second band (B41). One end of the filter 30C is connected to the input ends of the low-noise amplifiers 27 and 28, and the other end of the filter 30C is connected to the selection terminals 501B, 502B, and 503B of the switch circuit 50B. Specifically, the filter 30C has the input terminals 301B, 302B, and 303B, the output terminals 304B and 305B, the series-arm resonators 306B, 307B, and 308B, the switch circuit 309B, acoustic wave resonators 310C and 311C, and parallel-arm resonators 312C, 313C, and 314C.

The parallel-arm resonator 312C is an example of the first parallel-arm acoustic wave resonator and is connected between the ground and the path connecting the input terminal 301B and the selection terminal 3093B.

The parallel-arm resonator 313C is an example of the second parallel-arm acoustic wave resonator and is connected between the ground and the path connecting the input terminal 302B and the selection terminal 3094B.

The parallel-arm resonator 314C is an example of the third parallel-arm acoustic wave resonator and is connected between the ground and the path connecting the input terminal 303B and the selection terminal 3095B.

The acoustic wave resonator 310C is an example of the first acoustic wave resonator and is connected between the output terminal 304B and the common terminal 3091B of the switch circuit 309B. The acoustic wave resonator 310C is selectively connected, via the switch circuit 309B, to a set of the series-arm resonator 306B and the parallel-arm resonator 312C, a set of the series-arm resonator 307B and the parallel-arm resonator 313C, and a set of the series-arm resonator 308B and the parallel-arm resonator 314C. The resonant frequencies of the series-arm resonators 306B, 307B, and 308B and the anti-resonant frequencies of the parallel-arm resonators 312C, 313C, and 314C may be included in the first pass band, and the first pass band of the filter 30C may be formed by them.

The acoustic wave resonator 311C is an example of the second acoustic wave resonator and is connected between the output terminal 305B and the common terminal 3092B of the switch circuit 309B. The acoustic wave resonator 311C is selectively connected, via the switch circuit 309B, to a set of the series-arm resonator 306B and the parallel-arm resonator 312C, a set of the series-arm resonator 307B and the parallel-arm resonator 313C, and a set of the series-arm resonator 308B and the parallel-arm resonator 314C. The resonant frequencies of the series-arm resonators 306B, 307B, and 308B and the anti-resonant frequencies of the parallel-arm resonators 312C, 313C, and 314C may be included in the second pass band, and the second pass band of the filter 30C may be formed by them.

### 4.3. Summary

Also, for example, the filter 30C of the present embodiment may further have the parallel-arm resonator 312C connected between the ground and the path connecting the input terminal 301B and the selection terminal 3093B, the parallel-arm resonator 313C connected between the ground and the path connecting the input terminal 302B and the selection terminal 3094B, and the parallel-arm resonator 314C connected between the ground and the path connecting the input terminal 303B and the selection terminal 3095B.

In addition to the series-arm resonators 306B, 307B, and 308B, the parallel-arm resonators 312C, 313C, and 314C are thus connected to the selection terminals 501B, 502B, and 503B of the switch circuit 50B via the input terminals 301B, 302B, and 303B, respectively. Thus, it is possible to further reduce impedance drift in the other band capable of simultaneous communication when the filter 30C is seen from the selection terminals 501B, 502B, and 503B of the switch circuit 50B, and therefore to further reduce signal loss in the other bands upon simultaneous reception of a signal in the first or second band and a signal in each of the other bands (e.g., the third, fourth, and fifth bands).

### Other Embodiments

Although the acoustic wave filter and the high frequency filter according to the present disclosure have been described above based on the embodiments, the acoustic wave filter and the high frequency filter according to the present disclosure are not limited to the embodiments described above. The present disclosure also encompass other embodiments implemented by a combination of any given constituents in the above embodiments, modifications obtained by applying various modifications conceived of by those skilled in the art to the above embodiments without departing from the gist of the present disclosure, and various devices incorporating the above-described acoustic wave filter or the above-described high frequency circuit.

For example, in the circuit configurations of the various circuits according to the above embodiments, an additional circuit element, wiring, or the like may be inserted to paths connecting circuit elements and signal paths disclosed in the drawings. Specifically, for example, an impedance matching circuit may be inserted between a low-noise amplifier and a filter and/or between a filter and a switch circuit. For example, the impedance matching circuit is formed of, but not particularly limited to, an inductor and/or a capacitor.

Note that the high frequency circuits according to the above embodiments may include a transmission path.

The following demonstrates the characteristics of the acoustic wave filters and high frequency circuits described based on the above embodiments.
<1>

An acoustic wave filter having a pass band including a reception band which is a first band and a reception band which is a second band, the acoustic wave filter comprising:
a first input terminal and a second input terminal;
an output terminal;
a first switch circuit including a first common terminal, a first selection terminal, and a second selection terminal;
a first series-arm acoustic wave resonator connected between the first selection terminal and the first input terminal;
a second series-arm acoustic wave resonator connected between the second selection terminal and the second input terminal; and
an acoustic wave resonator connected between the first common terminal and the output terminal.
<2>

The acoustic wave filter according to <1>, wherein
a resonant frequency of the first series-arm acoustic wave resonator is included in the pass band of the acoustic wave filter.
<3>

The acoustic wave filter according to <2>, wherein
a resonant frequency of the second series-arm acoustic wave resonator is included in the pass band of the acoustic wave filter.
<4>

The acoustic wave filter according to any one of <1> to <3>, further comprising:
a first parallel-arm acoustic wave resonator connected between a ground and a path connecting the first input terminal and the first selection terminal; and
a second parallel-arm acoustic wave resonator connected between the ground and a path connecting the second input terminal and the second selection terminal.
<5>

A high frequency circuit comprising:
the acoustic wave filter according to any one of <1> to <4>;
a first filter having a pass band including a reception band which is a third band;
a second filter having a pass band including a reception band which is a fourth band; and
a second switch circuit including a second common terminal connected to an antenna connection terminal, a third selection terminal, and a fourth selection terminal, wherein
the third selection terminal is connected to the first input terminal of the acoustic wave filter and also connected to the first filter,
the fourth selection terminal is connected to the second input terminal of the acoustic wave filter and also connected to the second filter,
a combination of the first band and the third band is a band combination capable of simultaneous communication, and
a combination of the second band and the fourth band is a band combination capable of simultaneous communication.
<6>

The high frequency circuit according to <5>, further comprising:
a third filter connected to the third selection terminal and having a pass band including a reception band which is a fifth band; and
a fourth filter connected to the fourth selection terminal and having a pass band including a reception band which is a sixth band, wherein
a combination of the first band and the fifth band is a band combination capable of simultaneous communication, and
a combination of the second band and the sixth band is a band combination capable of simultaneous communication.
<7>

The high frequency circuit according to <6>, wherein
the second switch circuit further includes a fifth selection terminal,
the high frequency circuit further comprises
   a fifth filter connected to the fifth selection terminal and having a pass band including a reception band which is a seventh band, and
   a sixth filter connected to the fifth selection terminal and having a pass band including a reception band which is an eighth band, and
a combination of the seventh band and the eighth band is a band combination capable of simultaneous communication.
<8>

The high frequency circuit according to <7>, wherein
the second switch circuit further includes a sixth selection terminal,
the high frequency circuit further comprises a seventh filter connected to the sixth selection terminal and having a pass band including a reception band which is a ninth band, and
a combination of the first band and the ninth band and a combination of the second band and the ninth band are both a band combination capable of simultaneous communication.
<9>

The high frequency circuit according to <8>, wherein
the second switch circuit further includes a seventh selection terminal,
the high frequency circuit further comprises an eighth filter connected to the seventh selection terminal and having a pass band including a reception band which is a tenth band, and
a combination of the first band and the tenth band and a combination of the second band and the tenth band are both a band combination capable of simultaneous communication.
<10>

The high frequency circuit according to <9>, wherein
the first band is Band 1 for LTE or n1 for 5G NR,
the second band is Band 66 for LTE or n66 for 5G NR,
the third band is Band 3 for LTE or n3 for 5G NR,
the fourth band is Band 25 for LTE or n25 for 5G NR,
the fifth band is Band 40 for LTE or n40 for 5G NR,
the sixth band is Band 30 for LTE or n30 for 5G NR,
the seventh band is Band 34 for LTE or n34 for 5G NR,
the eighth band is Band 39 for LTE or n39 for 5G NR,
the ninth band is Band 7 for LTE or n7 for 5G NR, and
the tenth band is Band 41 for LTE or n41 for 5G NR.
<11>

An acoustic wave filter switchable between a first pass band including a reception band which is a first band and a second pass band including a reception band which is a second band, the acoustic wave filter comprising:
a first input terminal, a second input terminal, and a third input terminal;
a first output terminal and a second output terminal;
a first switch circuit including a first common terminal, a second common terminal, a first selection terminal, a second selection terminal, and a third selection terminal;
a first series-arm acoustic wave resonator connected between the first selection terminal and the first input terminal;
a second series-arm acoustic wave resonator connected between the second selection terminal and the second input terminal;
a third series-arm acoustic wave resonator connected between the third selection terminal and the third input terminal;
a first acoustic wave resonator connected between the first common terminal and the first output terminal; and
a second acoustic wave resonator connected between the second common terminal and the second output terminal.
<12>

The acoustic wave filter according to <11>, wherein
a resonant frequency of the first series-arm acoustic wave resonator is included in the first pass band and the second pass band of the acoustic wave filter.
<13>

The acoustic wave filter according to <12>, wherein
a resonant frequency of the second series-arm acoustic wave resonator is included in the first pass band and the second pass band of the acoustic wave filter.
<14>

The acoustic wave filter according to <13>, wherein
a resonant frequency of the third series-arm acoustic wave resonator is included in the first pass band and the second pass band of the acoustic wave filter.
<15>

The acoustic wave filter according to any one of <11> to <14>, further comprising:
a first parallel-arm acoustic wave resonator connected between a ground and a path connecting the first input terminal and the first selection terminal;
a second parallel-arm acoustic wave resonator connected between the ground and a path connecting the second input terminal and the second selection terminal; and
a third parallel-arm acoustic wave resonator connected between the ground and a path connecting the third input terminal and the third selection terminal.
<16>

A high frequency circuit comprising:
the acoustic wave filter according to any one of <11> to <15>;
a first filter having a pass band including a reception band which is a third band;
a second filter having a pass band including a reception band which is a fourth band;
a third filter having a pass band including a reception band which is a fifth band; and
a second switch circuit including a third common terminal connected to an antenna connection terminal, a fourth selection terminal, a fifth selection terminal, and a sixth selection terminal, wherein
the fourth selection terminal is connected to the first input terminal of the acoustic wave filter and also connected to the first filter,
the fifth selection terminal is connected to the second input terminal of the acoustic wave filter and also connected to the second filter,
the sixth selection terminal is connected to the third input terminal of the acoustic wave filter and also connected to the third filter,
at least one of a combination of the first band and the third band and a combination of the second band and the third band is a band combination capable of simultaneous communication,
at least one of a combination of the first band and the fourth band and a combination of the second band and the fourth band is a band combination capable of simultaneous communication, and
at least one of a combination of the first band and the fifth band and a combination of the second band and the fifth band is a band combination capable of simultaneous communication.
<17>

The high frequency circuit according to <16>, further comprising:
a fourth filter connected to the fourth selection terminal and having a pass band including a reception band which is a sixth band;
a fifth filter connected to the fifth selection terminal and having a pass band including a reception band which is a seventh band; and
a sixth filter connected to the sixth selection terminal and having a pass band including a reception band which is an eighth band, wherein
at least one of a combination of the first band and the sixth band and a combination of the second band and the sixth band is a band combination capable of simultaneous communication,
at least one of a combination of the first band and the seventh band and a combination of the second band and the seventh band is a band combination capable of simultaneous communication, and
at least one of a combination of the first band and the eighth band and a combination of the second band and the eighth band is a band combination capable of simultaneous communication.
<18>

The high frequency circuit according to <17>, further comprising:
a seventh filter connected to the fourth selection terminal and having a pass band including a reception band which is a ninth band; and
an eighth filter connected to the fifth selection terminal and having a pass band including a reception band which is a tenth band, wherein
at least one of a combination of the first band and the ninth band and a combination of the second band and the ninth band is a band combination capable of simultaneous communication, and
at least one of a combination of the first band and the tenth band and a combination of the second band and the tenth band is a band combination capable of simultaneous communication.
<19>

The high frequency circuit according to <18>, wherein
the first band is Band 7 for LTE or n7 for 5G NR,
the second band is Band 41 for LTE or n41 for 5G NR,
the third band is Band 3 for LTE or n3 for 5G NR,
the fourth band is Band 25 for LTE or n25 for 5G NR,
the fifth band is Band 40 for LTE or n40 for 5G NR,
the sixth band is Band 30 for LTE or n30 for 5G NR,
the seventh band is Band 34 for LTE or n34 for 5G NR,
the eighth band is Band 39 for LTE or n39 for 5G NR,
the ninth band is Band 1 for LTE or n1 for 5G NR, and
the tenth band is Band 66 for LTE or n66 for 5G NR.

The present disclosure can be used widely for communication devices such as mobile phones as an acoustic wave filter and a high frequency circuit disposed at the front end part.

What is claimed is:

1. An acoustic wave filter comprising:
a first input terminal and a second input terminal;
an output terminal;
a first switch circuit comprising a first common terminal, a first selection terminal, and a second selection terminal;
a first series-arm acoustic wave resonator connected between the first selection terminal and the first input terminal;
a second series-arm acoustic wave resonator connected between the second selection terminal and the second input terminal; and
an acoustic wave resonator connected between the first common terminal and the output terminal,
wherein the acoustic wave filter has a pass band that includes a first reception band and a second reception band.

2. The acoustic wave filter according to claim 1, wherein a resonant frequency of the first series-arm acoustic wave resonator is in the pass band of the acoustic wave filter.

3. The acoustic wave filter according to claim 2, wherein a resonant frequency of the second series-arm acoustic wave resonator is in the pass band of the acoustic wave filter.

4. The acoustic wave filter according to claim 1, further comprising:
a first parallel-arm acoustic wave resonator connected between ground and a path that connects the first input terminal to the first selection terminal; and
a second parallel-arm acoustic wave resonator connected between ground and a path that connects the second input terminal to the second selection terminal.

5. A high frequency circuit comprising:
the acoustic wave filter according to claim 1;
a first filter having a pass band including a third reception band;
a second filter having a pass band including a fourth reception band; and
a second switch circuit comprising a second common terminal connected to an antenna connection terminal, a third selection terminal, and a fourth selection terminal,
wherein the third selection terminal is connected to the first input terminal and to the first filter,
wherein the fourth selection terminal is connected to the second input terminal and to the second filter,
wherein the first reception band and the third reception band together are simultaneous communication bands, and
wherein the second reception band and the fourth reception band together are simultaneous communication bands.

6. The high frequency circuit according to claim 5, further comprising:
a third filter connected to the third selection terminal and having a pass band including a fifth reception band; and
a fourth filter connected to the fourth selection terminal and having a pass band including a sixth reception band,
wherein the first reception band and the fifth reception band together are simultaneous communication bands, and
wherein the second reception band and the sixth reception band together are simultaneous communication bands.

7. The high frequency circuit according to claim 6, further comprising:
a fifth filter connected to a fifth selection terminal of the second switch circuit, and having a pass band including comprising a seventh reception band; and
a sixth filter connected to the fifth selection terminal and having a pass band including an eighth reception band,
wherein the seventh reception band and the eighth reception band together are simultaneous communication bands.

8. The high frequency circuit according to claim 7, further comprising:
a seventh filter connected to a sixth selection terminal of the second switch circuit, and having a pass band including a ninth reception band,
wherein the first reception band and the ninth reception band together are simultaneous communication bands, and
wherein the second reception band and the ninth reception band together are simultaneous communication bands.

9. The high frequency circuit according to claim 8, further comprising:
an eighth filter connected to a seventh selection terminal of the second switch circuit, and having a pass band including a tenth reception band,
wherein the first reception band and the tenth reception band together are simultaneous communication bands, and
wherein the second reception band and the tenth reception band together are simultaneous communication bands.

10. The high frequency circuit according to claim 9, wherein:
the first reception band is Band 1 for Long Term Evolution (LTE) or n1 for Fifth Generation New Radio (5G NR),
the second reception band is Band 66 for LTE or n66 for 5G NR,
the third reception band is Band 3 for LTE or n3 for 5G NR,
the fourth reception band is Band 25 for LTE or n25 for 5G NR,
the fifth reception band is Band 40 for LTE or n40 for 5G NR,
the sixth reception band is Band 30 for LTE or n30 for 5G NR,
the seventh reception band is Band 34 for LTE or n34for 5G NR,
the eighth reception band is Band 39 for LTE or n39 for 5G NR,
the ninth reception band is Band 7 for LTE or n7 for 5G NR, and
the tenth reception band is Band 41 for LTE or n41 for 5G NR.

11. An acoustic wave filter configured to switch between a first pass band and a second pass band, the acoustic wave filter comprising:
a first input terminal, a second input terminal, and a third input terminal;
a first output terminal and a second output terminal;
a first switch circuit comprising a first common terminal, a second common terminal, a first selection terminal, a second selection terminal, and a third selection terminal;
a first series-arm acoustic wave resonator connected between the first selection terminal and the first input terminal;
a second series-arm acoustic wave resonator connected between the second selection terminal and the second input terminal;
a third series-arm acoustic wave resonator connected between the third selection terminal and the third input terminal;
a first acoustic wave resonator connected between the first common terminal and the first output terminal; and
a second acoustic wave resonator connected between the second common terminal and the second output terminal,
wherein the first pass band includes a first reception and the second pass band includes a second reception band.

12. The acoustic wave filter according to claim 11, wherein a resonant frequency of the first series-arm acoustic wave resonator is in the first pass band and in the second pass band of the acoustic wave filter.

13. The acoustic wave filter according to claim 12, wherein a resonant frequency of the second series-arm acoustic wave resonator is in the first pass band and in the second pass band of the acoustic wave filter.

14. The acoustic wave filter according to claim 13, wherein a resonant frequency of the third series-arm acoustic wave resonator is in the first pass band and in the second pass band of the acoustic wave filter.

15. The acoustic wave filter according to claim 11, further comprising:
a first parallel-arm acoustic wave resonator connected between ground and a path that connects the first input terminal to the first selection terminal;
a second parallel-arm acoustic wave resonator connected between ground and a path that connects the second input terminal to the second selection terminal; and
a third parallel-arm acoustic wave resonator connected between ground and a path that connects the third input terminal to the third selection terminal.

16. A high frequency circuit comprising:
acoustic wave filter according to claim 11;
a first filter having a pass band including a third reception band;
a second filter having a pass band including a fourth reception band;
a third filter having a pass band including a fifth reception band; and
a second switch circuit comprising a third common terminal connected to an antenna connection terminal, a fourth selection terminal, a fifth selection terminal, and a sixth selection terminal,
wherein the fourth selection terminal is connected to the first input terminal and to the first filter,
wherein the fifth selection terminal is connected to the second input terminal and to the second filter,
wherein the sixth selection terminal is connected to the third input terminal and to the third filter,
wherein the first reception band and the reception third band together, or the second reception band and the third reception band together, are simultaneous communication bands,
wherein the first reception band and the fourth reception band together, or the second reception band and the fourth reception band together, are simultaneous communication bands, and
wherein the first reception band and the fifth reception band together, or the second reception band and the fifth reception band together, are simultaneous communication bands.

17. The high frequency circuit according to claim 16, further comprising:
a fourth filter connected to the fourth selection terminal and having a pass band including a sixth reception band;
a fifth filter connected to the fifth selection terminal and having a pass band including a seventh reception band; and
a sixth filter connected to the sixth selection terminal and having a pass band including an eighth reception band,
wherein the first reception band and the sixth reception band together, or the second reception band and the sixth reception band together, are simultaneous communication bands,
wherein the first reception band and the seventh reception band together, or the second reception band and the seventh reception band together, are simultaneous communication bands, and
wherein the first reception band and the eighth reception band together, or the second reception band and the eighth reception band together, are simultaneous communication bands.

18. The high frequency circuit according to claim 17, further comprising:
a seventh filter connected to the fourth selection terminal and having a pass band including a ninth reception band; and
an eighth filter connected to the fifth selection terminal and having a pass band including a tenth reception band,
wherein the first reception band and the ninth reception band together, or and the second reception band and the ninth reception band together, are simultaneous communication bands, and
wherein the first reception band and the tenth reception band together, or the second reception band and the tenth reception band together, are simultaneous communication bands.

19. The high frequency circuit according to claim 18, wherein:
the first reception band is Band 7 for Long Term Evolution (LTE) or n7 for Fifth Generation New Radio (5G NR),
the second reception band is Band 41 for LTE or n41 for 5G NR,
the third reception band is Band 3 for LTE or n3 for 5G NR,
the fourth reception band is Band 25 for LTE or n25 for 5G NR,
the fifth reception band is Band 34 for LTE or n34 for 5G NR,
the sixth reception band is Band 40 for LTE or n40 for 5G NR,
the seventh reception band is Band 30 for LTE or n30 for 5G NR,
the eighth reception band is Band 39 for LTE or n39 for 5G NR,
the ninth reception band is Band 1 for LTE or n1 for 5G NR, and
the tenth reception band is Band 66 for LTE or n66 for 5G NR.
